(19) United States
(12) Patent Application Publication
(10) Pub. No.: US 2013/0186450 A1
(43) Pub. Date: Jul. 25, 2013

(54) Solar Power System

(71) Applicant: Seldon Energy Partners, LLC, Dallas, TX (US)

(72) Inventors: Mark Berry Smith, Dallas, TX (US); David Charles Bisig, JR., Dripping Springs, TX (US); William Tol Harris, Georgetown, TX (US)

(73) Assignee: Seldon Energy Partners, LLC, Dallas, TX (US)

(21) Appl. No.: 13/747,147

(22) Filed: Jan. 22, 2013

Related U.S. Application Data
(60) Provisional application No. 61/589,708, filed on Jan. 23, 2012.
(60) Provisional application No. 61/589,705, filed on Jan. 23, 2012.

(51) Int. Cl. H01L 31/045; H01L 31/042

(52) U.S. Cl. CPC H01L 31/045; H01L 31/0424
USPC 136/245

(57) ABSTRACT

A solar power system includes a solar power arm comprising a solar power array, the solar power arm configurable between a transport configuration and a deployed configuration and a container configured to receive the solar power arm when the solar power arm is in the transport configuration.

### CROSS-REFERENCE TO RELATED APPLICATIONS

The present application claims priority to U.S. Provisional Patent Application No. 61/589,708, filed on Jan. 23, 2012 by Mark Berry Smith, et al., entitled “System and Method for Portable Solar Array Deployment,” and U.S. Provisional Patent Application No. 61/589,705, filed on Jan. 23, 2012 by Mark Berry Smith, et al., entitled “Solar Power System,” which are both incorporated by reference herein as if reproduced in their entireties.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

Some sources of electrical energy provide electrical power at undesirably high cost, with inconvenient power quality characteristics, and/or are not environmentally friendly. Some applications that consume electrical power are located relatively remote from conveniently available commercial electrical grid systems. Some applications that consume electrical power are temporary in nature and may not be suitable for connection to commercial electrical grid systems to receive electrical energy from the commercial grid systems or to provide electrical energy to the commercial grid systems. Some solar power systems are configured as permanent installations and/or are not readily deployable and/or may not be suitable for convenient use at successively different geographic locations. Some solar power systems are not configured for industrial applications such as for providing greater than about 1 kW capacity, two phase or three phase alternating current, and/or voltages greater than about 110VAC.

### SUMMARY

In some embodiments of the disclosure, a solar power system is provided that comprises a solar power arm comprising a solar power array, the solar power arm configurable between a transport configuration and a deployed configuration, and a container configured to receive the solar power arm when the solar power arm is in the transport configuration.

In other embodiments of the disclosure, a solar power arm is provided that comprises a first frame, a second frame joined to the first frame by a hinge, and at least one solar power array carried by each of the first frame and the second frame, wherein the first frame and the second frame are movable relative to each other between (1) a transport configuration in which the first frame and the second frame substantially abut each with the solar power arrays substantially parallel to each other and substantially facing at least one of away from each other and toward each other and (2) a deployed configuration in which the first frame and the second frame are disposed substantially end to end so that the solar power arrays are substantially parallel to each other and substantially face a same direction.

In yet other embodiments of the disclosure, a method is provided that comprises providing a container comprising a solar power arm in a transport configuration, moving the solar power arm from the transport configuration to an intermediate configuration in which at least a portion of the solar power arm remains within the container and at least a portion of the solar power arm extends from the container, wherein the solar power arm is substantially folded within the container when the solar power arm is in the transport configuration.

### BRIEF DESCRIPTION OF THE DRAWINGS

For a more complete understanding of the present disclosure and the advantages thereof, reference is now made to the following brief description, taken in connection with the accompanying drawings and detailed description:

FIG. 1 is an oblique view of a solar power system in a deployed configuration according to an embodiment of the disclosure;

FIG. 2 is an oblique view of the solar power system of FIG. 1 in a transport configuration;

FIG. 3 is an oblique view of the solar power system of FIG. 1 in an intermediate configuration;

FIG. 4 is a front view of a solar array of the solar power system of FIG. 1;

FIG. 5 is a back view of the solar array of FIG. 4;

FIG. 6 is an oblique view of a solar arm of the solar power system of FIG. 1 in an intermediate configuration;

FIG. 7 is a close up view of a panel separator support of a frame of the solar arm of FIG. 6;

FIG. 8 is a close up view of a hinge of a frame of the solar arm of FIG. 6;

FIG. 9 is a close up view of the solar arm of FIG. 6 in a collapsed or transport configuration;

FIG. 10 is a close up view of the solar arm of FIG. 9 with wheels attached;

FIG. 11 is a close up view of the solar arm of FIG. 6 in a fully extended or deployed configuration;

FIG. 12 is an end view of a container of the solar power system of FIG. 1;

FIG. 13 is a side view of the container of FIG. 12;

FIG. 14 is another side view of the container of FIG. 12;

FIG. 15 shows a solar arm supported by optional weighted anchors is shown;

FIG. 16 shows a solar arm outfitted with an automated position adjustment device;

FIG. 17 shows a solar power system comprising various sizes of solar power arms; and

FIG. 18 shows a plurality of interconnected solar power systems.

### DETAILED DESCRIPTION

This disclosure provides, in some embodiments, systems and methods for providing portable, rapidly deployable, and rapidly removable solar power energy while imparting a minimal amount of environmental damage as a result of the deployment of the solar power system. In some embodiments, the solar power systems disclosed herein may be configured to provide direct current from about 0.01 Volts to about 1500 Volts and/or alternating current ranging from less than about 0.01 Volts to about 1200 Volts and above. In some embodiments, the solar power systems disclosed herein may be configured to provide single-phase, two-phase, and/or three-phase power. In some embodiments, the solar power systems disclosed herein may generally utilize one or more photovoltaic cells configured to provide electrical current to one or more batteries or charge controllers for batteries. In some embodiments, the batteries may feed power inverters, rectifiers, transformers, and/or other electrical components to supply a selected type of electrical power from the options described above. Further and more detailed disclosure and discussion of the electrical systems of the solar power systems disclosed herein may be found in the U.S. Provisional Patent Application No. 61/589,708 of the same Applicants of this disclosure and which was filed on Jan. 23, 2012 and entitled “System and Method for Portable Solar Array Deployment.” It will be appreciated that while some systems and components common to this disclosure and U.S. Provisional Patent Application No. 61/589,708 may be illustrated, described, labeled, and/or configured differently, the combination of disclosures is not inconsistent in substance and variations should be interpreted as alternative embodiments comprising combinations of the varied descriptions.

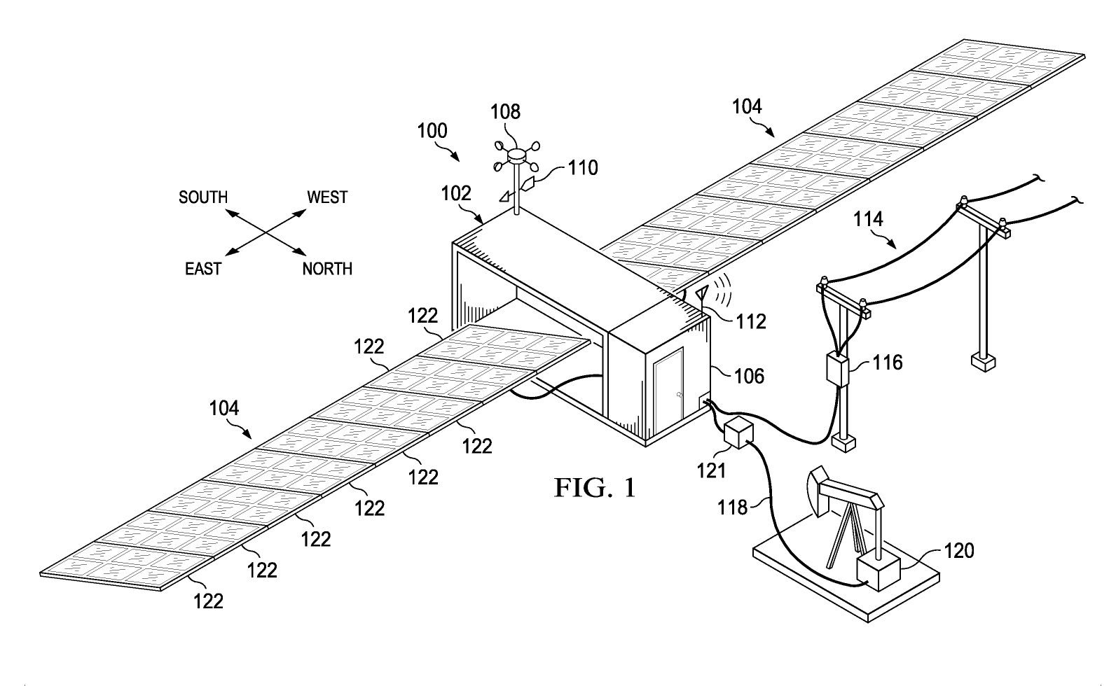

Referring now to FIG. 1 in the drawings, a solar power system 100 is shown as deployed to an oil-producing pump site. Generally, the solar power system 100 comprises a transportable container 102, a plurality of solar arms 104, and an electrical control room 106. The container 102 may comprise a cargo box or shipping type container or other skid or trailer mounted box-like enclosure or pad. The container may be sized and shaped so that transportation of the container 102 is convenient and/or allowed by rail, tractor-trailer over public roadways, shipping at sea, and/or may be configured to be carried by helicopter and/or other aircraft. Regardless the mode of transport, the container 102 may be configured to serve as a delivery package for the solar power system 100 by selectively housing the components of the solar arms 104, the control room 106, and any other components necessary to generate solar power while the solar power system 100 is in a transport configuration.

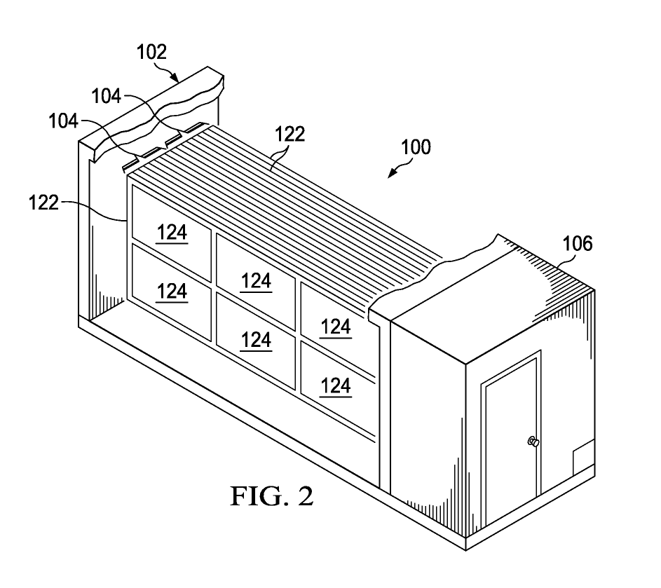

Referring now to FIG. 2, the solar power system 100 is shown in a transport configuration where the components of solar arms 104 are substantially housed within the container 102. In some embodiments, the container 102 may comprise large access ports on the sides of the container 102 to allow easy insertion and removal of the components of the solar arms 104. For example, in embodiments where the container 102 is a shipping container, substantial portions of the sidewalls may be removed. In some embodiments, tarpaulins or other removable covers and/or walls may be used to more completely enclose the interior of the container 102 when the solar power system 100 is in a transport configuration.

Referring back to FIG. 1, the solar power system 100 is shown as further comprising an anemometer 108 for measuring, monitoring, and/or reporting wind speed and a weather vane 110 for measuring, monitoring, and/or reporting wind direction. The solar power system 100 is shown as further comprising a remote and/or wireless communication device 112 for measuring, monitoring, and/or reporting the status of the status of the solar power system 100 and/or the environment in which the solar power system 100 is disposed. The wireless communication device 112 may further receive instructions for controlling any of the electrical systems of the solar power system 100 and/or for controlling any automated, mechanized, and/or selectively actuated aspects of the solar power system 100. The solar power system 100 may comprise electrical components external to the control room 106 and such components may be mounted relatively closer to a source of commercial electrical power 114 in a remote enclosure 116. In some embodiments, a circuit breaker or electrical disconnect device may be associated with the remote disclosure to selectively connect and disconnect the solar power system 100 to the commercial electrical grid 114. In some embodiments, the solar power system 100 may comprise a circuit breaker or electrical disconnect device 121 to selectively connect and disconnect the load 120 from the solar power system 100. Additionally, the solar power system 100 may comprise a load line 118 that supplies electrical energy to a load 120. In the embodiment shown, the load 120 may comprise an electrical motor configured to cause mechanical reciprocation of a component of an oil pump.

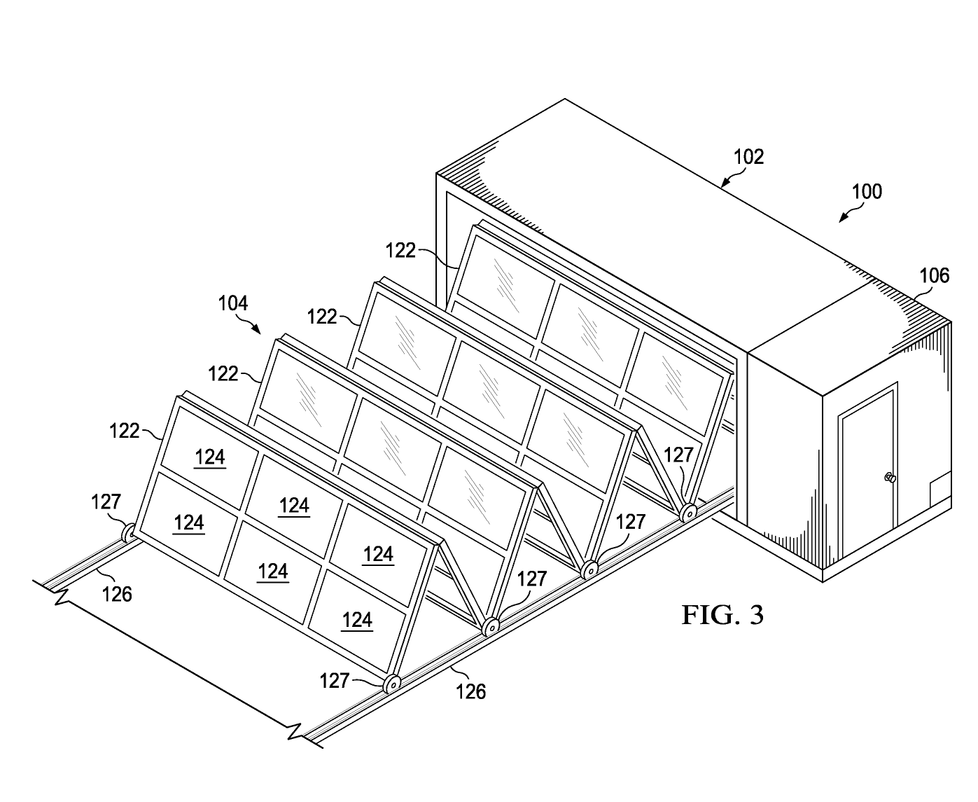

Referring now to FIG. 3, solar power system 100 is shown in an intermediate configuration in which a solar arm 104 is no longer fully stored within the container 102 but is also not yet fully deployed to the deployed configuration shown in FIG. 1. FIG. 3 shows that solar arm 104 comprises a plurality of solar arrays 122 and it will be appreciated that each solar array 122 comprises a plurality of photovoltaic solar panels 124. FIG. 3 further shows that solar power system 100 may comprise one or more tracks 126 and/or channel devices configured to guide deployment of the solar arm 104 from the transportation configuration to the deployed configuration. In some embodiments, the tracks 126 may be retractable into a recess of the container 102 and/or extension and/or retraction of the tracks may be mechanized and/or automated. Further, to better utilize the tracks 126, one or more of the solar arrays 122 may comprise wheels 127 configured to fit within the tracks 126. It will be appreciated that in some embodiments, wheels 127 may be physically connected to the frames 128 of solar arrays 122. However, in alternative embodiments, wheels 127 may be physically connected to solar panels 124. In alternative embodiments where no track exists, one or more of the solar arrays 122 may be temporarily or permanently provided with wheels and/or tires configured to roll over rough terrain. In some embodiments one or more of the wheels and/or tires may themselves be motorized to assist in deployment and/or retraction of the solar arms 104. In some embodiments, cables, winches, brakes, and/or any other suitable mechanical aide may be temporarily and/or permanently attached to one or more of the tracks 126, solar arms 104, container 102, and/or any other suitable component of the solar power system 100 to assist in deployment and/or retraction of the solar arms 104.

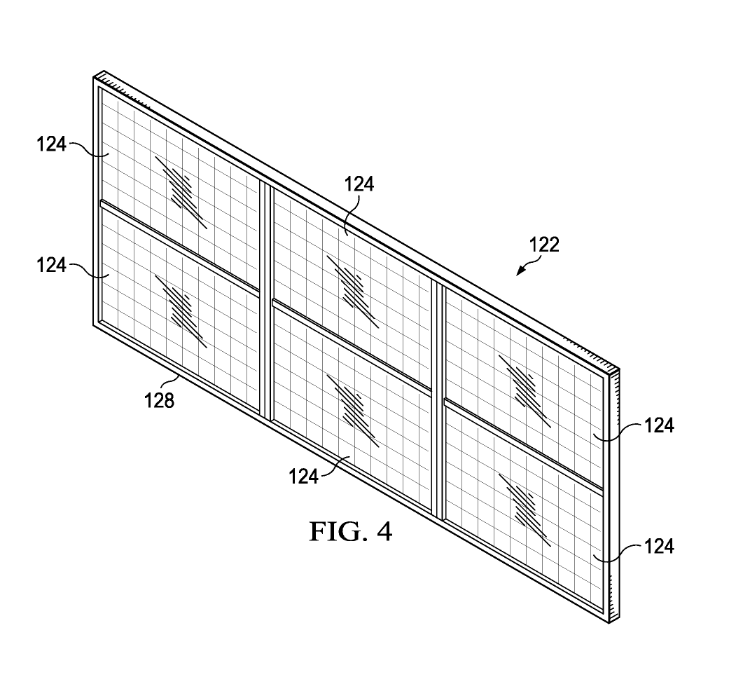

Referring now to FIG. 4, a front view of a single solar array 122 is shown. The solar array 122 comprises a frame 128 configured to retain a plurality of solar panels 124 and a substantially parallel and planar arrangement relative to each other. In some embodiments, the frame 128 may be constructed of steel such as, but not limited to, steel channel beams. In some embodiments, a front to back thickness of the frame 128 may be greater than a front to back thickness of solar panels 124.

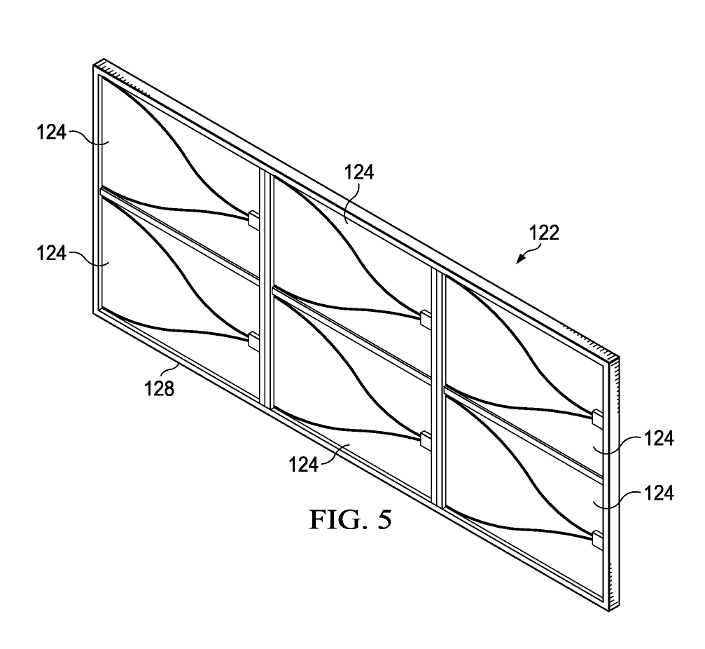

Referring now to FIG. 5, a back view of a single solar array 122 is shown. In this embodiment, the front to back thickness of the frame 128 is configured to house the control wiring and control box of each solar panel 124. As will be explained further, the housing the control wiring and control box of each solar panel 124 within the associated frames 128, the control wiring and control locks of each solar panel 124 do not protrude and prevent abutment of solar arrays 122.

Referring now to FIG. 6, a solar arm 104 comprising a plurality of frames 128 is shown in an intermediate configuration. For clarity, the solar arm 104 is shown without solar panels 124. In this embodiment, adjacent frames 128 are connected to each other via hinges 130. In this embodiment, hinges 130 may comprise so-called piano hinges that extend along a substantial portion of the length of the frames 128. In alternative embodiments, adjacent frames 128 may be connected using any other suitable hinge, tether, and/or intermediate mechanical device.

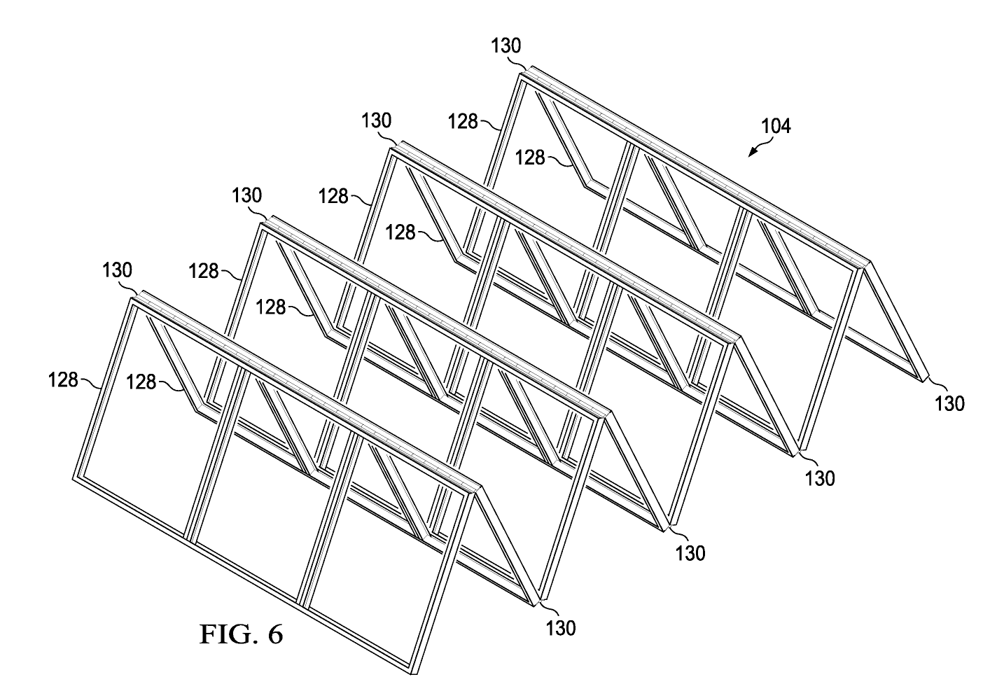

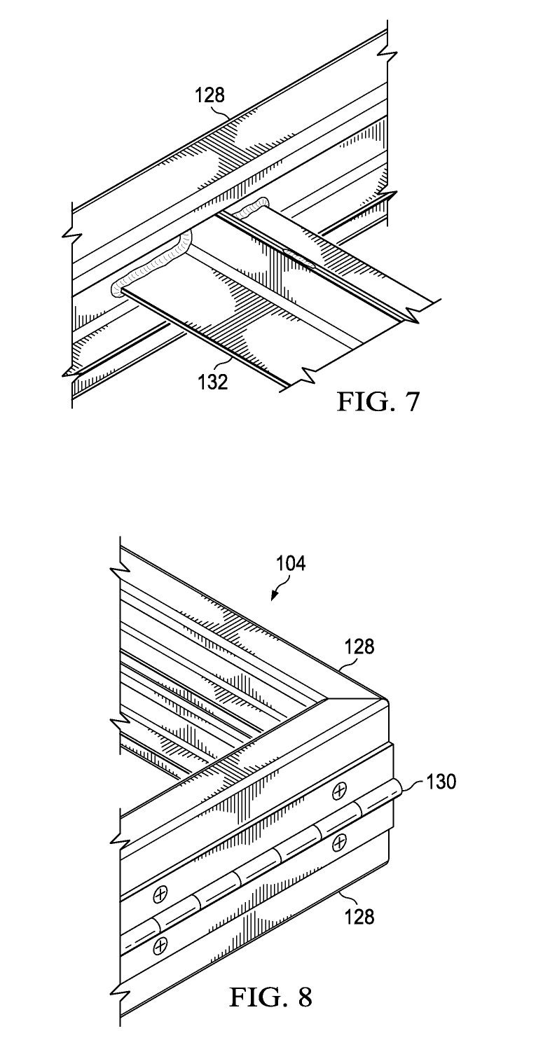

Referring now to FIG. 7, a close up view of a panel separator support 132 of the frame 128 is shown.

Referring now to FIG. 8, a close up view of a hinge 130 joining two adjacent frames 128 is shown.

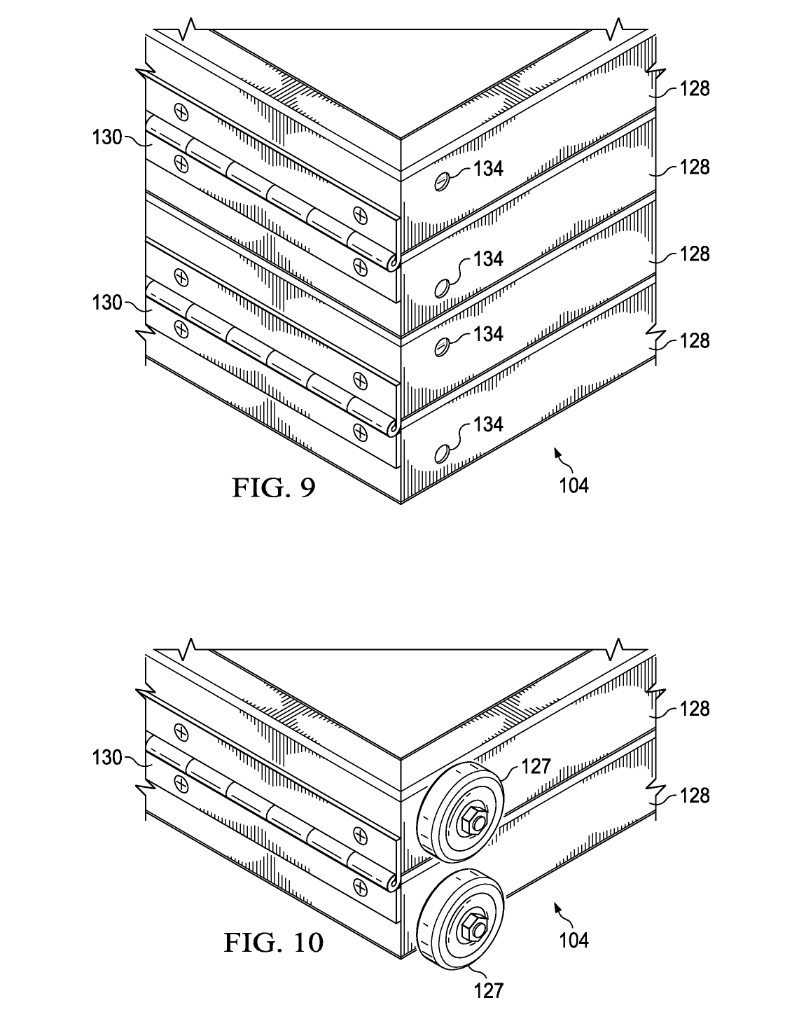

Referring now to FIG. 9, a close up view of a collapsed solar arm 104 is shown. In this embodiment, frames 128 are provided with mounting holes 134, some of which may receive bolts, axles, and/or other wheel and/or tire mounting hardware.

Referring now to FIG. 10, a close up view of a collapsed solar arm 104 is shown with wheels attached to ease deployment and/or retraction of the solar arm 104. It will be appreciated that selection of wheel locations may be chosen to prevent adjacent wheels from contacting each other in a manner that may limit collapse of the solar arm 104.

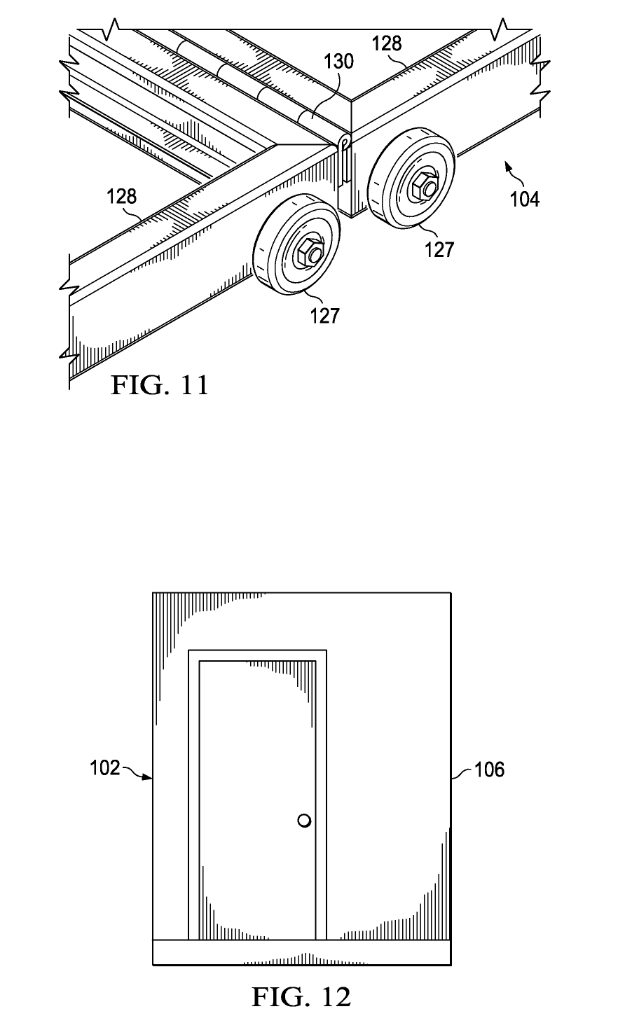

Referring now to FIG. 11, a close up view of a solar arm 104 in a fully extended position is shown. In this embodiment, the solar arm 104 may roll on wheels even while the solar arm 104 lies substantially parallel to the ground and is fully extended.

Referring now to FIG. 12, an end view of the container 102 is shown. The container 102 comprises the control room 106 which may be a so-called finished room or enclosure suitable for housing any electrical components of the solar power system and protecting the electrical components from weather and/or environmental contaminants. In some embodiments, the load line 118 may extend from the control room 106. In such cases, it may be advantageous to position the control room 106 end of the container 102 as near the load 120 as possible and to thereafter provide a load line 118 of minimal necessary length. In some cases, substantial power loss due to an unnecessarily long load line 118 may be prevented.

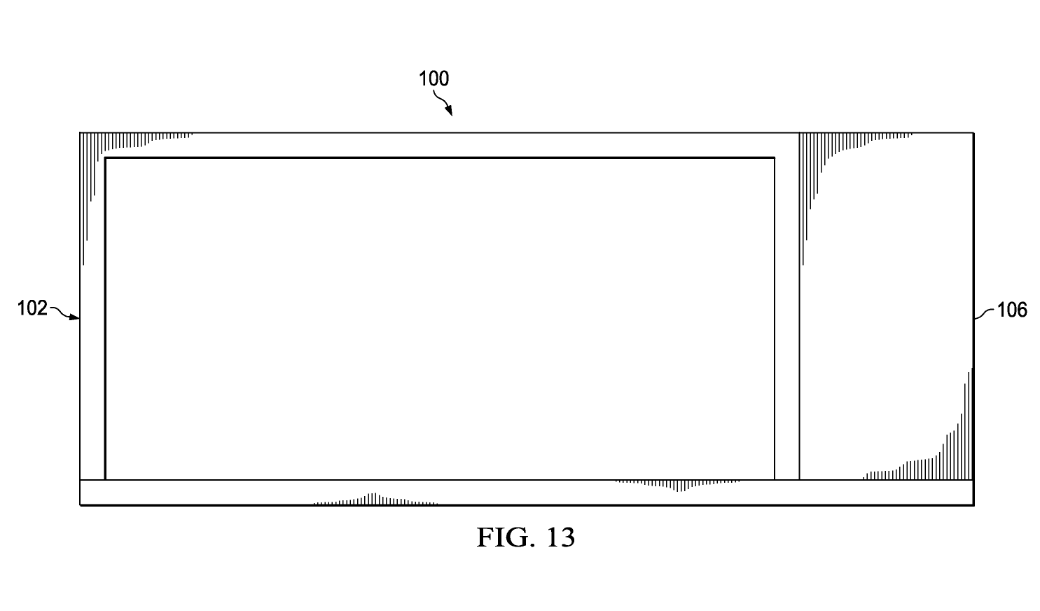

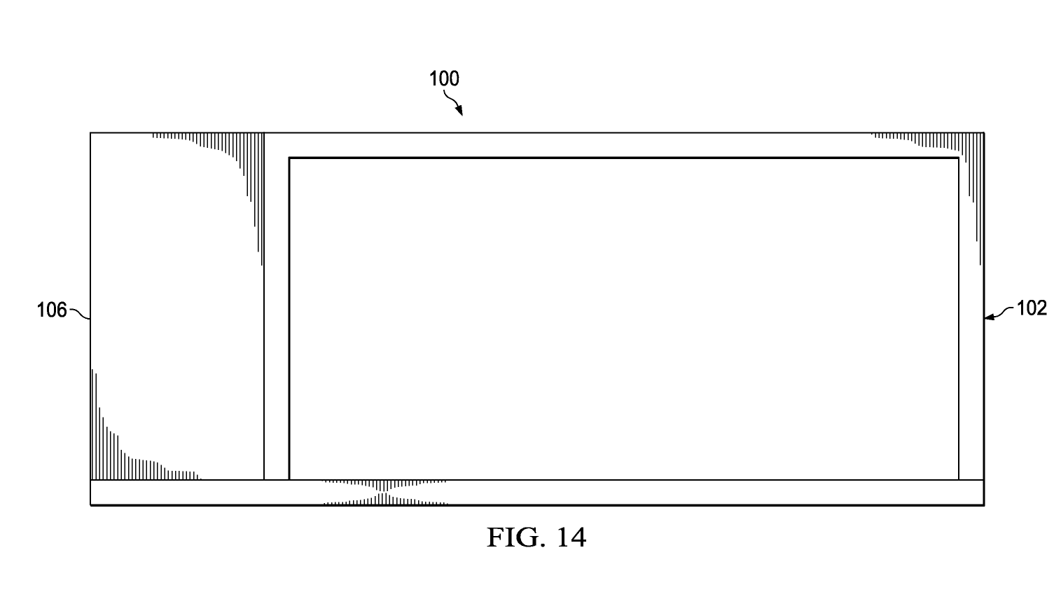

Referring now to FIGS. 13 and 14, side views of the container 102 are shown that illustrate the general structure of the container 102 including the open sides relative to the control room 106.

In operation, the solar power system 100 of FIGS. 1-14 may be easily transported to a site and deployed to provide electrical power. Similarly, the solar power system 100 may be easily retracted and/or converted from the deployed configuration to a transportation configuration to once again make the solar power system 100 ready for transport and/or relocation, perhaps to provide electrical power while located at another geographic location.

In some embodiments, the solar power system 100 may be substantially fully contained and/or self-contained within the container 102. The container 102 may be loaded via winch, forklift, crane, and/or any other suitable method of placing the container 102 onto a trailer, boat, truck, and/or any other suitable means of transporting the container 102.

Upon arriving at a deployment destination for the solar power system 100, delivery personnel may orient the control room 106 to be nearer an electrical load 120 than the other end of the container 102. Next, the container 102 may be separated from and/or unloaded from the delivery vehicle. Once the container 102 is situated on the ground and/or other support surface, the above-described tarpaulins may be removed to allow access to the interior of the container 102. Next, tracks 126 may be located on the ground and/or other support surface to make rolling of the solar arms 104 into the fully deployed position easier.

With tracks 126 in position, deployment personnel may manually unfold the solar arms 104 by pulling an outermost frame 128 of each solar arm 104 away from the container 102. Alternatively, motors, wenches, cables, and/or other mechanical aides may be utilized to accomplish the above-described outward movement of the outermost frame 128 of each solar arm 104. With continued movement of the outermost frame 128 of each solar arm 104 away from the container 102, each solar arm 104 may eventually reach a fully deployed configuration in which each of the solar arrays 122 of a solar arm are substantially parallel and/or generally coplanar and/or flat.

In some embodiments, the container 102 may be positioned so that a front and back of the container 102 are aligned along a North-South direction so that when the solar arms 104 are deployed may extend away from the container 102 in an East-West direction. With each solar arm 104 substantially fully deployed in the above-described East-West direction, deployment personnel with or without the use of the above-described mechanical aides may lift, tilt, and/or rotate each solar arm 104 substantially as a single unit in a desired direction relative to a vector of incoming sunlight. Once a desired orientation relative to the above-described vector is obtained, the solar arms 104 may be secured in position. In some embodiments, a metal frame may be joined between a solar arm 104 and the container and may serve to stabilize the solar arm 104 and the above-described selected position relative to the vector.

Next, the anemometer 108 and/or wind vane 110 may be located on the container or at some other location suitable for providing information to the control room 106 and/or other electrical system control components. Additionally, electrical connections may be made between the control room 106 and/or its electrical control system components and the load 120, remote enclosure 116, and solar arms 104. With such electrical connections made and with the solar arms in such position, the electrical control system may be caused to begin generating electrical energy and/or delivering electrical power to load 120 and/or the commercial power grid 114. In some embodiments, remote enclosure 116 and selective connection to the commercial power grid 114 are optional components and/or features associated with solar power system 100. In some embodiments, delivery of the electrical power to load 120 may cause an oil pump to operate.

In order to discontinue use of the solar power system 100, electrical control system may be caused to cease generation and/or delivery of electrical energy and the above-described steps for deploying the solar power system 100 may generally be performed in the reverse and/or opposite order to once again result in the solar power system 100 being housed substantially fully within the container 102 and ready for relocation and/or removal from the site of previous operation.

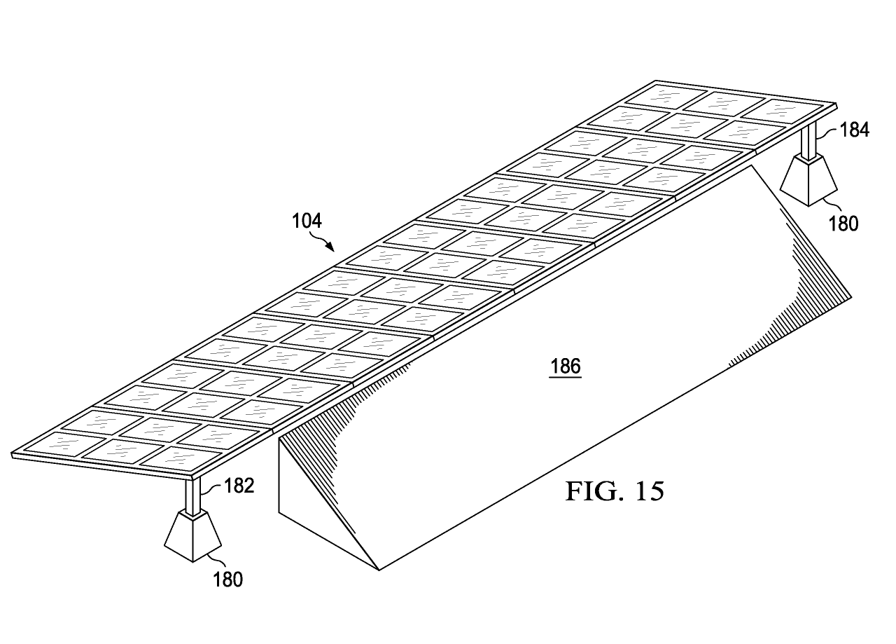

Referring now to FIG. 15, a solar arm 104 is shown as being optionally supported by weighted anchors 180. In some embodiments, the solar arm 104 may not only be supported by the anchors 180 but also be tethered to the anchors to combat any lifting force produced by wind movement relative to the solar arm 104. In some embodiments, the anchors may comprise components configured to selectively extend and/or retract, thereby altering a position of the solar arm 104. In some embodiments, the anchor 180 may comprise an air ram 182 while in other embodiments an equalized hydraulic ram 184 may be used. Further, the solar arm 104 is shown as being associated with a wind dam or shield 186 that may alleviate any undesirable lifting force produced by wind movement relative to the solar arm 104. In alternative embodiments, any other suitable device may be provided to reduce wind loads on the solar arm 104.

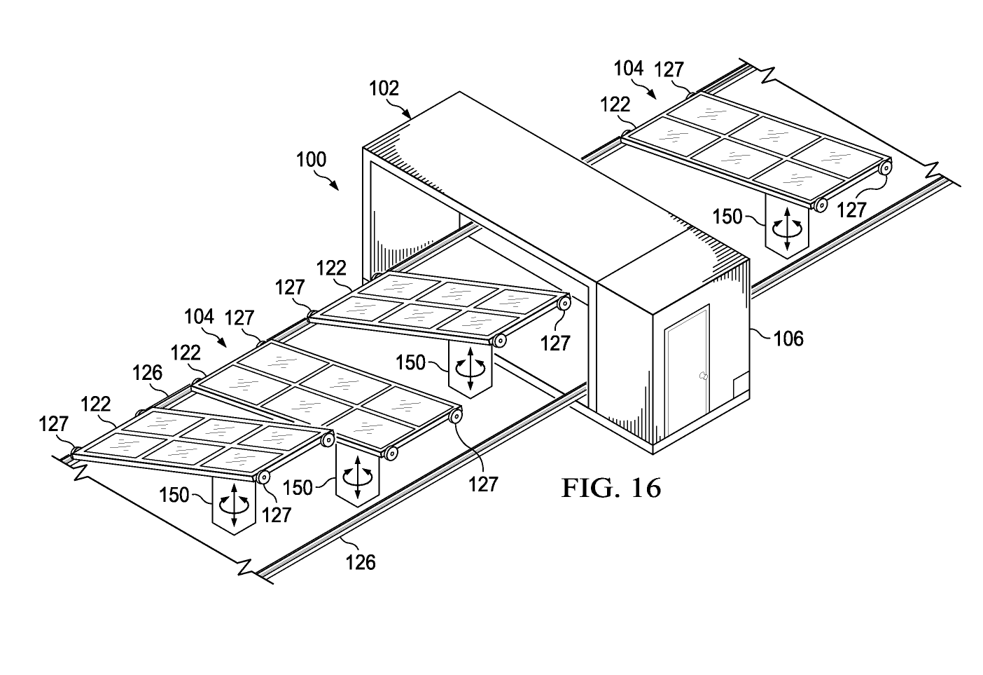

Referring now to FIG. 16, a solar arm 104 may be outfitted with one or more mechanized and/or automated position adjustment devices 150. In some embodiments, a position adjustment device 150 may provide for tilt and/or rotation of the solar arm 104 to control the orientation of the solar arm 104 relative to the sun and/or a vector of sunlight. In some embodiments, the electrical control system may be programmed to control the position adjustment device 150, a user may manually control the position adjustment devices 150 on site or remotely, and/or the electrical control system may automatically track the position of the sun based on light sensor feedback and/or changes in electrical power generation. Still further, in alternative embodiments, a solar arm 104 may comprise a plurality of solar arrays 122 that are not connected in the above-described foldable configuration. Instead, in some embodiments, one or more of the solar arrays may be independent of each other and may be outfitted with one or more of their own position adjustment devices 150. In some embodiments, adjustment of a position of one or more of solar arms 104, solar arrays 122, frames 128, and solar panels 124 may be accomplished using a predetermined schedule of time dependent positions. In some embodiments, the time dependent positions may comprise computer tables of proper tilt for a given time and the proper tilt may vary dependent upon the latitude and longitude of the location of the solar power system 100.

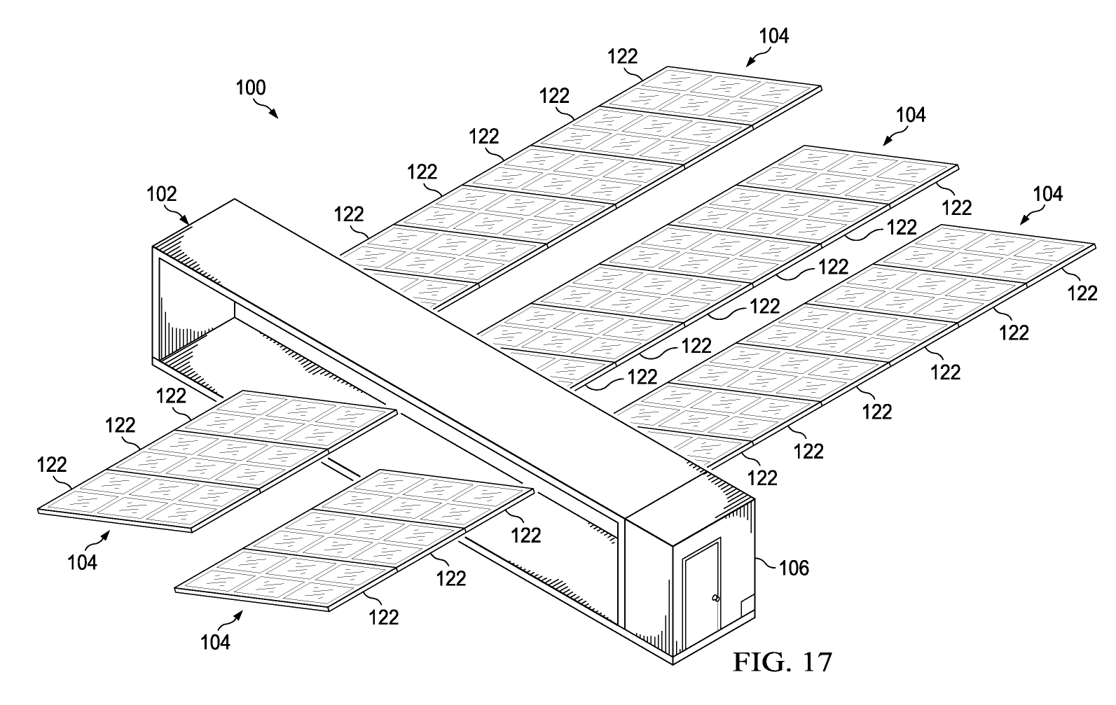

Referring now to FIG. 17, a solar power system 100 is shown as comprising solar power arms 104 of different dimensions and quantities on the left and right side of the container 102. In alternative embodiments, solar power arms 104 may be of any other suitable size and/or shape so long as the solar power arms 104 may be substantially received into the container 102 for transport.

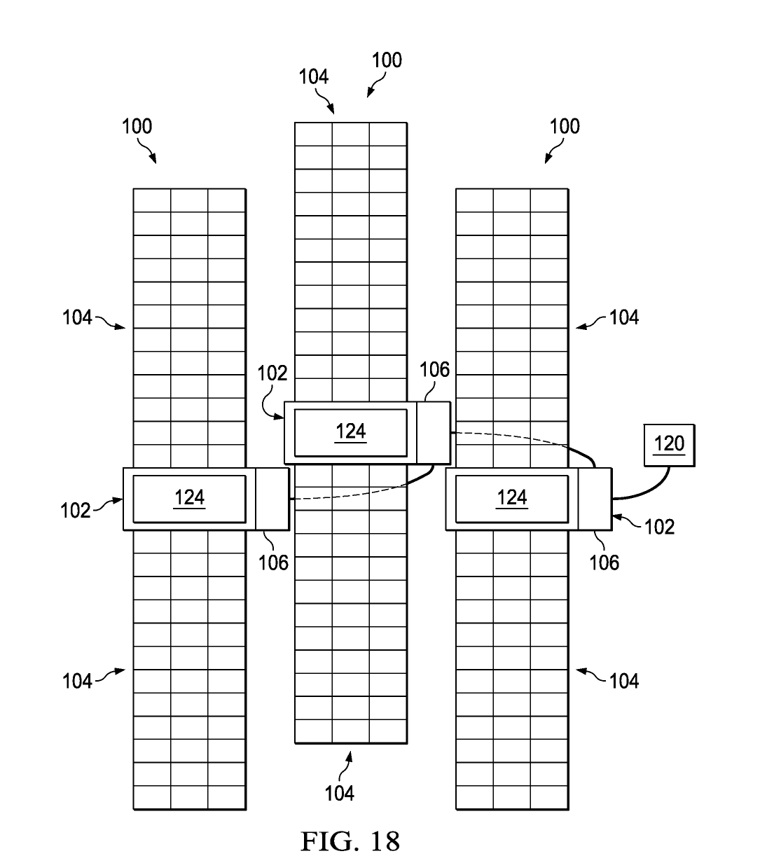

Referring now to FIG. 18, it is shown that a plurality of solar power systems 100 may be deployed in close proximity to each other, electrically connected, and cooperatively operated to supply electrical power to a load 120.

In some embodiments, a solar power system 100 may occupy about 3000 ft.². In alternative embodiments, the solar power system 100 may occupy more or less than about 3000 ft.². In some embodiments, wind speed, wind direction, wind predictions, and/or precipitation predictions and/or presence may be monitored to activate an alarm, an automatic mechanical response for moving solar power arms 104, and/or any other suitable action for preventing and/or reducing damage to solar power system 100 as a result of undesirable environmental conditions. In some embodiments, solar power arms 104 may be automatically retracted into container 102 and response to a wind speed and/or wind direction exceeding a predetermined threshold. In some embodiments, a container 102 may comprise an overall length of about 10-40 feet, however, in alternative embodiments the overall length may be less than 10 feet or more than 40 feet. In some embodiments, solar power arms 104 may be controlled to cut through wind rather than retain a preset position and become damaged by wind. In some embodiments, a single solar power arm 104 may weigh about 4000 lbs, a single solar array 122 may weigh about 500 lbs, and a single solar panel 124 may weigh about 50 lbs. In some embodiments, a battery bank may weigh about 3500 lbs. In some embodiments, the solar power arms 104 may not be attached to the container 102 while deployed while in other embodiments, the solar power arms 104 may maintain at least one connection to the container 102 at all times.

In some embodiments, the solar power system 100 may be useful for powering an oil pump at a producing oil well. In other embodiments, the solar power system 100 may be used to power a long haul gas pipeline compressor station, a water well, a fracturing job liquid pump, and/or a remote telecommunication site that may be associated with a remote telecommunication tower.

In alternative embodiments, the solar power arms 104 may be configured to comprise a transport and/or storage configuration different than described above and the solar power arms 104 may be deployed from storage in the container 102 in a different manner than described above. Nonetheless, in some alternative embodiments, the solar power system 100 comprises a feature and/or component that ensures an at least partially physically constrained deployment of the solar power arms 104 from the storage configuration in the container 102 to the fully deployed configuration. In some embodiments, the at least partial physical constraint of the solar power arms 104 may apply when the solar power arms 104 are configured in an intermediate configuration between the storage configuration and the fully deployed configuration. In some embodiments, the intermediate constraint may be a component and/or feature of the solar power arms 104 themselves while in other embodiments, the intermediate constraint may comprise features and/or components external to the solar power arms 104.

At least one embodiment is disclosed and variations, combinations, and/or modifications of the embodiment(s) and/or features of the embodiment(s) made by a person having ordinary skill in the art are within the scope of the disclosure. Alternative embodiments that result from combining, integrating, and/or omitting features of the embodiment(s) are also within the scope of the disclosure. Where numerical ranges or limitations are expressly stated, such express ranges or limitations should be understood to include iterative ranges or limitations of like magnitude falling within the expressly stated ranges or limitations (e.g., from about 1 to about 10 includes, 2, 3, 4, etc.; greater than 0.10 includes 0.11, 0.12, 0.13, etc.). For example, whenever a numerical range with a lower limit, Rl, and an upper limit, Ru, is disclosed, any number falling within the range is specifically disclosed. In particular, the following numbers within the range are specifically disclosed: R=Rl+k*(Ru−Rl), wherein k is a variable ranging from 1 percent to 100 percent with a 1 percent increment, i.e., k is 1 percent, 2 percent, 3 percent, 4 percent, 5 percent, . . . 50 percent, 51 percent, 52 percent, . . . 95 percent, 96 percent, 97 percent, 98 percent, 99 percent, or 100 percent. Moreover, any numerical range defined by two R numbers as defined in the above is also specifically disclosed. Use of the term “optionally” with respect to any element of a claim means that the element is required, or alternatively, the element is not required, both alternatives being within the scope of the claim. Use of broader terms such as comprises, includes, and having should be understood to provide support for narrower terms such as consisting of, consisting essentially of, and comprised substantially of. Accordingly, the scope of protection is not limited by the description set out above but is defined by the claims that follow, that scope including all equivalents of the subject matter of the claims. Each and every claim is incorporated as further disclosure into the specification and the claims are embodiment(s) of the present invention. Further, while the claims herein are provided as comprising specific dependencies, it is contemplated that any claims may depend from any other claims and that to the extent that any alternative embodiments may result from combining, integrating, and/or omitting features of the various claims and/or changing dependencies of claims, any such alternative embodiments and their equivalents are also within the scope of the disclosure.

What is claimed is:

1. A solar power system, comprising:
a solar power arm comprising a solar power array, the solar power arm configurable between a transport configuration and a deployed configuration; and
a container configured to receive the solar power arm when the solar power arm is in the transport configuration.

2. The solar power system of claim 1, wherein the solar power arm is foldable.

3. The solar power system of claim 1, wherein the solar power arm comprises a hinge that joins a first frame of the solar power arm to a second frame of the solar power arm.

4. The solar power system of claim 3, wherein each of the first frame and the second frame carry at least one solar power array.

5. The solar power system of claim 1, further comprising:
a track configured to receive a wheel of the solar power arm.

6. The solar power system of claim 5, wherein the wheel is movable along the track when moving the solar power arm between the transport configuration and the deployed configuration.

7. The solar power system of claim 1, wherein the solar power arm is movable to track movement of a source of light.

8. The solar power system of claim 1, wherein the container is configured as a cargo container suitable for transport by a tractor-trailer.

9. A solar power arm, comprising:
a first frame;
a second frame joined to the first frame by a hinge; and
at least one solar power array carried by each of the first frame and the second frame;
wherein the first frame and the second frame are movable relative to each other between (1) a transport configuration in which the first frame and the second frame substantially abut each with the solar power arrays substantially parallel to each other and substantially facing at least one of away from each other and toward each other and (2) a deployed configuration in which the first frame and the second frame are disposed substantially end to end so that the solar power arrays are substantially parallel to each other and substantially face a same direction.

10. The solar power arm of claim 9, comprising a wheel configured to enable rolling translation of at least one of the first frame and the second frame relative to a support structure when the solar power arm is moved between the transport configuration and the deployed configuration.

11. The solar power arm of claim 9, comprising an automated support device configured to selectively assist a direction in which at least one of the solar power arrays faces.

12. The solar power arm of claim 9, wherein each solar power array comprises a plurality of solar power panels.

13. The solar power arm of claim 9, wherein the first frame is configurable to direct the solar power array of the first frame to a light source located at a first location and wherein the second frame is configurable to direct the solar power array of the second frame to a light source located at a second location that is different than the first location.

14. The solar power arm of claim 9, wherein the first frame and the second frame are connected to each other by a piano hinge.

15. A method, comprising:
providing a container comprising a solar power arm in a transport configuration;
moving the solar power arm from the transport configuration to an intermediate configuration in which at least a portion of the solar power arm remains within the container and at least a portion of the solar power arm extends from the container;
wherein the solar power arm is substantially folded within the container when the solar power arm is in the transport configuration.

16. The method of claim 15, further comprising:
providing a track extending away from the container and moving the solar power arm along the track.

17. The method of claim 16, wherein the movement of the solar power arm along the track is assisted by a motor.

18. The method of claim 15, further comprising:
extending the solar power arm to a substantially flat deployed configuration.

19. The method of claim 18, further comprising:
moving the solar power arm to track a source of light while maintaining the substantially flat deployed configuration.

20. The method of claim 18, further comprising:
moving a first frame of the solar power arm to aim a first solar power array toward a first location; and
moving a second frame of the solar power arm to aim a second solar power array toward a second location.
